(19) United States
(12) Patent Application Publication
(10) Pub. No.: US 2025/0197722 A1
(43) Pub. Date: Jun. 19, 2025

(54) RED-EMITTING NITRIDOPHOSPHATE PHOSPHOR AND WHITE PHOSPHOR-CONVERTED LED

(71) Applicant: LUMLEDS LLC, San Jose, CA (US)

(72) Inventors: Peter Josef Schmidt, Aachen (DE); Wolfgang Schnick, Gauting (DE); Reinhard Pritzl, München (DE); Philipp-Jean Strobel, München (DE); Thomas Diederich, Stolberg (DE)

(73) Assignee: LUMILEDS LLC, San Jose, CA (US)

(21) Appl. No.: 18/540,203

(22) Filed: Dec. 14, 2023

(51) Int. Cl. C09K 11/77; H01L 33/32; H01L 33/50

(52) U.S. Cl. CPC C09K 11/7738; H10H 20/8512; C09K 2211/182; H10H 20/0361; H10H 20/825

(57) ABSTRACT

An inventive luminescent material suitable for use as a phosphor for an LED includes a nitridophosphate material having a general formula AE_{y-x}Li_{10-2y}P₄N₁₀:Euₓ, wherein (i) AE includes one or more of Ca, Sr, or Ba, and (ii) y≥x>0. In some instances, y can equal 2 and x can be between 0 and 0.1. In some instances, AE can include only Ca; in some other instances, AE can include a majority amount of Ca and lesser amounts of Sr or Ba. In some instances, the luminescent material can exhibit a peak emission wavelength greater than 600 nm.

### FIELD OF THE INVENTION

The invention relates generally to phosphor-converted light emitting diodes (pcLEDs).

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths. In some instances the light emitted by the LED is used as the output of a device; such LEDs can be referred to as direct emitters.

In other instances LEDs can be combined with one or more wavelength-converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer.

Phosphor-converted LEDs may be designed so that all of the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED.

Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Multiple LEDs or pcLEDs can be formed together on a single substrate to form an array. Such arrays can be employed to form active illuminated displays, such as those employed in, e.g., smartphones and smart watches, computer or video displays, signage, or visualization systems (such as augmented- or virtual-reality displays), to form adaptive illumination sources, such as those employed in, e.g., automotive headlights, street lighting, camera flash sources, or flashlights (i.e., torches). An array having one or several or many individual devices per millimeter (e.g., device pitch or spacing of about a millimeter, a few hundred microns, or less than 100 microns, and separation between adjacent devices less than 100 microns or only a few tens of microns or less) typically is referred to as a miniLED array or a microLED array (alternatively, a μLED array). Such mini- or microLED arrays can in many instances also include phosphor converters as described above; such arrays can be referred to as pc-miniLED or pc-microLED arrays.

### SUMMARY

An inventive luminescent material suitable for use as a phosphor for an LED comprises a nitridophosphate material having a general formula AE_{y-x}Li_{10-2y}P₄N₁₀:Euₓ, wherein (i) AE includes one or more of Ca, Sr, or Ba, and (ii) y≥x>0. In some instances, y can equal 2 and x can be between 0 and 0.1. In some instances, AE can include only Ca; in some other instances, AE can include a majority amount of Ca and lesser amounts of Sr or Ba. In some instances, the luminescent material can exhibit a peak emission wavelength greater than 600 nm.

Objects and advantages pertaining to pcLEDs, pc-miniLED arrays, and pc-microLED arrays may become apparent upon referring to the examples illustrated in the drawings and disclosed in the following written description or appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 shows a schematic cross-sectional view of an example pcLED.

FIGS. 2A and 2B show, respectively, cross-sectional and top schematic views of an example array of pcLEDs. FIG. 2C shows a top schematic view of an example miniLED or microLED array and an enlarged section of 3×3 LEDs of the array.

FIG. 3A shows a schematic cross-sectional view of an example array of pcLEDs arranged with respect to waveguides and a projection lens. FIG. 3B shows an arrangement similar to that of FIG. 3A, but without the waveguides.

FIG. 4A shows a schematic top view an example electronics board on which an array of pcLEDs may be mounted, and FIG. 4B similarly shows an example array of pcLEDs mounted on the electronic board of FIG. 4A.

FIGS. 5A, 5B, and 5C illustrate schematically the crystalline structure of an example inventive nitridophosphate luminescent material. FIG. 5D illustrates an X-ray diffraction pattern of an example inventive nitridophosphate luminescent material. FIG. 5E is an electron micrograph of a sample of an example inventive nitridophosphate luminescent material. FIGS. 5F and 5G are tables of crystallographic data of an example inventive nitridophosphate luminescent material. FIG. 5H illustrates low-temperature emission spectra of an example inventive nitridophosphate luminescent material.

FIGS. 6A and 6B illustrate emission and absorption spectra, respectively, of an example inventive nitridophosphate luminescent material and several conventional CASN luminescent materials.

FIG. 7A is a table showing phosphor compositions that include a green-emitting luminescent material mixed with an example inventive nitridophosphate luminescent material and with four example conventional SCASN or CASN luminescent materials. FIGS. 7B and 7C illustrate output spectra resulting from the mixtures of FIG. 7A.

The examples depicted are shown only schematically; all features may not be shown in full detail or in proper proportion; for clarity certain features or structures may be exaggerated or diminished relative to others or omitted entirely; the drawings should not be regarded as being to scale unless explicitly indicated as being to scale. For example, individual LEDs may be exaggerated in their vertical dimensions or layer thicknesses relative to their lateral extent or relative to substrate or phosphor thicknesses. The examples shown should not be construed as limiting the scope of the present disclosure or appended claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the inventive subject matter. The detailed description illustrates by way of example, not by way of limitation, the principles of the inventive subject matter. For purposes of simplicity and clarity, detailed descriptions of well-known devices, circuits, and methods may be omitted so as not to obscure the description of the inventive subject matter with unnecessary detail.

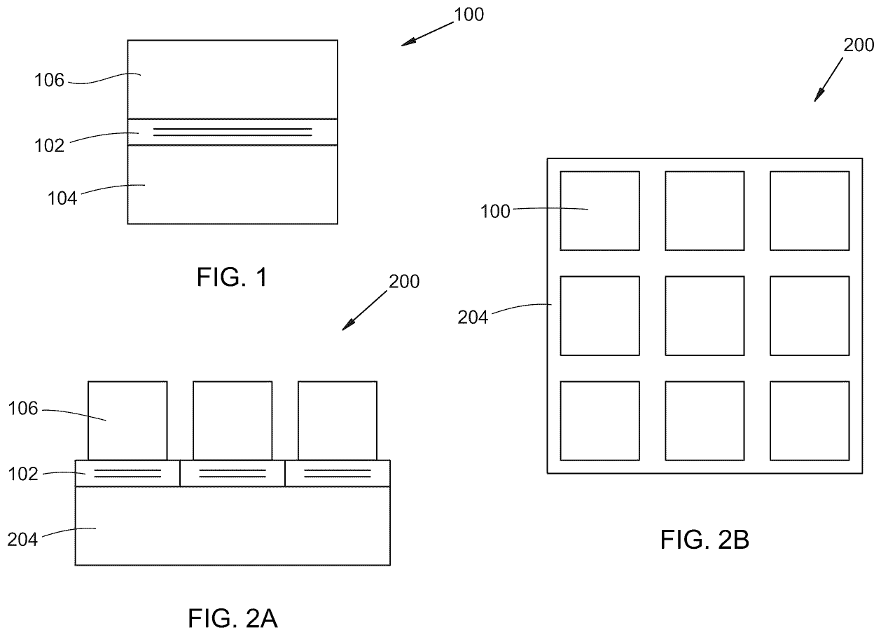

FIG. 1 shows an example of an individual pcLED 100 comprising a semiconductor light-emitting diode (LED) structure 102 disposed on a substrate 104, and a wavelength-converting structure (e.g., phosphor layer) 106 disposed on the semiconductor LED.

The semiconductor LED structure 102 typically comprises a junction or active region disposed between n-type and p-type layers. Application of a suitable forward bias across the semiconductor LED structure 102 results in emission of light from the active region. The wavelength of the emitted light (i.e., the first wavelength) is determined by the composition and structure of the active region. The semiconductor LED 102 may be, for example, a Ill-Nitride LED that emits blue, violet, or ultraviolet light. LEDs formed from any other suitable material system and that emit any other suitable wavelength of light may also be used. Other suitable material systems may include, for example, Ill-Phosphide materials, III-Arsenide materials, other binary, ternary, or quaternary alloys of gallium, aluminum, indium, nitrogen, phosphorus, arsenic, other III-V materials, or various II-VI materials.

Many suitable luminescent materials may be used for or incorporated into the wavelength-converting structure 106, depending on the desired optical output from the pcLED. At least a portion of the first light is absorbed by a luminescent material of the wavelength-converting structure 106, which in turn emits light at a second wavelength that is longer than the first wavelength. In some examples the wavelength-converting structure can include one or more additional luminescent materials that absorb light at the first wavelength and emit light at one or more corresponding additional wavelengths that are longer than the first wavelength. The light output of the pcLED includes the light emitted at the second wavelength by the luminescent material of the wavelength-converting structure, and can also include the light emitted by the one or more additional luminescent materials (if present) of the wavelength-converting structure 106. In some examples the light output of the pcLED 100 can include some of the light emitted by the semiconductor LED structure 102 at the first wavelength; in some other examples light at the first wavelength can be absent from, or only negligibly present in, the light output of the pcLED 100.

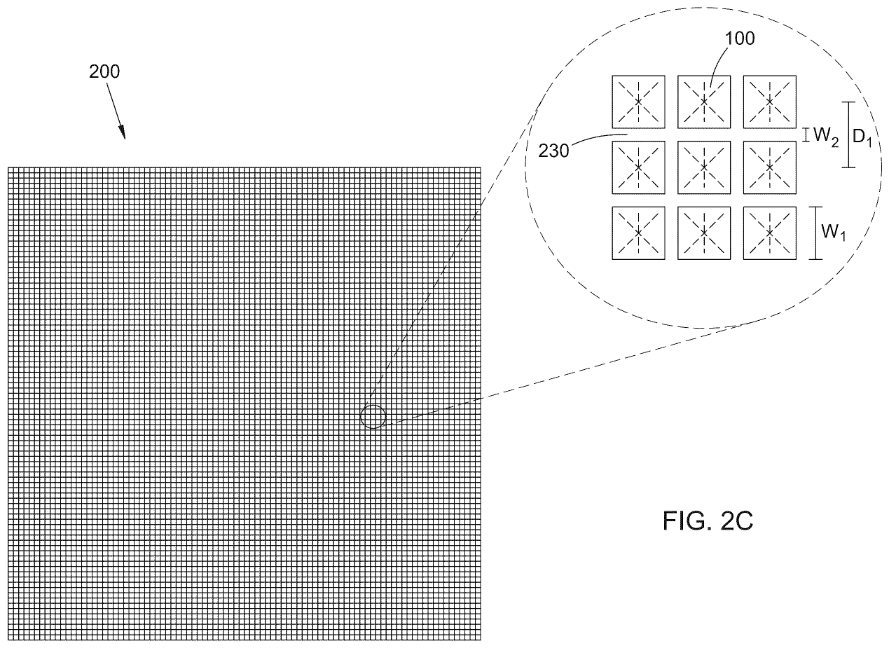

FIGS. 2A-2B show, respectively, cross-sectional and top views of a 3×3 array 200 of pcLEDs 100, each including a phosphor pixel 106, disposed on a substrate 204. Generally an array can include any suitable number of LEDs arranged in any suitable manner. In the illustrated example the array is depicted as formed monolithically on a shared substrate, but alternatively an array can be formed from separate individual LEDs and/or pcLEDs (e.g., singulated devices that are assembled onto an array substrate). Individual phosphor pixels 106 are shown in the illustrated example, but alternatively a continuous layer of phosphor material can be disposed across multiple semiconductor LEDs 102. In some instances the array 200 can include light barriers (e.g., reflective, scattering, and/or absorbing) between adjacent semiconductor LEDs 102, phosphor pixels 106, or both. Substrate 204 may optionally include electrical traces or interconnects, or CMOS or other circuitry for driving the LED, and may be formed from any suitable materials.

Although FIGS. 2A and 2B show a 3×3 array of nine pcLEDs, such arrays may include for example on the order of 10¹, 10², 10³, 10⁴, or more LEDs and or pcLEDs, e.g., as illustrated schematically in FIG. 2C. Individual LEDs 100 (i.e., pixels) may have widths w₁ (e.g., side lengths) in the plane of the array 200, for example, less than or equal to 1 millimeter (mm), less than or equal to 500 microns, less than or equal to 100 microns, or less than or equal to 50 microns. LEDs 100 in the array 200 may be spaced apart from each other by streets, lanes, or trenches 230 having a width w₂ in the plane of the array 200 of, for example, hundreds of microns, less than or equal to 100 microns, less than or equal to 50 microns, less than or equal to 20 microns, less than or equal to 10 microns, or less than or equal to 5 microns. The pixel pitch or spacing D₁ is the sum of w₁ and w₂. Although the illustrated examples show rectangular pixels arranged in a symmetric matrix, the pixels and the array may have any suitable shape or arrangement, whether symmetric or asymmetric. Multiple separate arrays of LEDs can be combined in any suitable arrangement in any applicable format to form a larger combined array or display.

LEDs having dimensions w₁ in the plane of the array (e.g., side lengths) of less than or equal to about 0.10 millimeters microns are typically referred to as microLEDs, and an array of such microLEDs may be referred to as a microLED array. LEDs having dimensions w₁ in the plane of the array (e.g., side lengths) of between about 0.10 millimeters and about 1.0 millimeters are typically referred to as miniLEDs, and an array of such miniLEDs may be referred to as a miniLED array.

The individual LEDs (pixels) in an LED array may be individually addressable, may be addressable as part of a group or subset of the pixels in the array, or may not be addressable. Thus, light emitting pixel arrays are useful for any application requiring or benefiting from fine-grained intensity, spatial, and temporal control of light distribution. These applications may include, but are not limited to, precise special patterning of emitted light from pixel blocks or individual pixels, in some instances including the formation of images as a display device. Depending on the application, emitted light may be spectrally distinct, adaptive over time, and/or environmentally responsive. The light emitting pixel arrays may provide preprogrammed light distribution in various intensity, spatial, or temporal patterns. The emitted light may be based at least in part on received sensor data and may be used for optical wireless communications. Associated electronics and optics may be distinct at a pixel, pixel block, or device level.

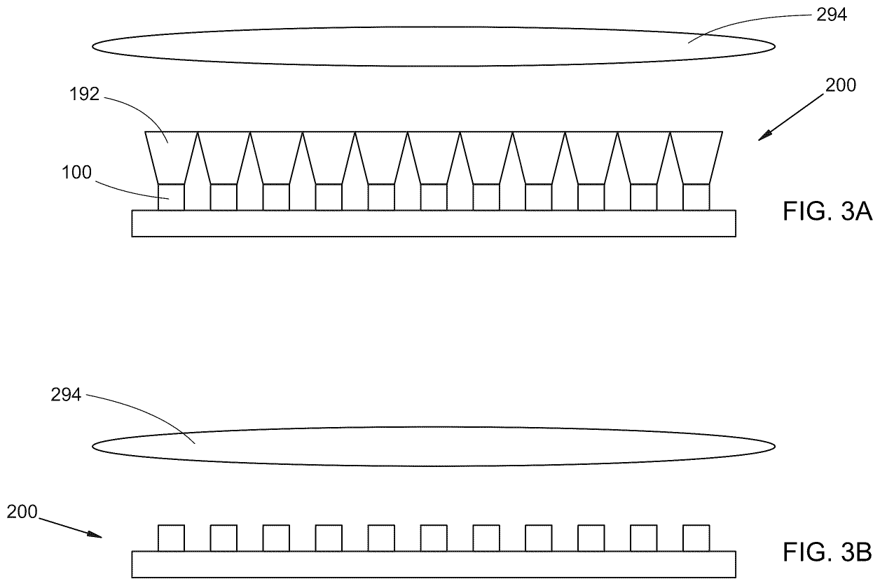

Individual pcLEDs 100 may optionally incorporate or be arranged in combination with a lens or other optical element located adjacent to or disposed on the phosphor layer. Such an optical element, not shown in the figures, may be referred to as a “primary optical element” and may be of any suitable type of arrangement (e.g., conventional refractive or diffractive optical elements, or so-called nanostructured optical elements such as those disclosed in U.S. Pat. No. 11,327,283, U.S. Pub. No. 2020/0343416, U.S. Pub. No. 2020/0335661, U.S. Pub. No. 2021/0184081, U.S. Pub. No. 2022/0146079, or U.S. Pub. No. 2022/0393076, each of which is incorporated by reference in its entirety). In addition, as shown in FIGS. 3A and 3B, a pcLED array 200 (for example, mounted on an electronics board) can be arranged in combination with secondary optical elements such as waveguides, lenses, or both for use in an intended application (for the entire array, for subsets thereof, or for individual pixels; of any suitable type or arrangement, e.g., conventional refractive or diffractive optical elements, or so-called nanostructured optical elements, including any of those listed above). In FIG. 3A, light emitted by each pcLED 100 of the array 200 is collected by a corresponding waveguide 192 and directed to a projection lens 294. Projection lens 294 may be a Fresnel lens, for example. This arrangement may be suitable for use, for example, in automobile headlights or other adaptive illumination sources. Other primary or secondary optical elements of any suitable type or arrangement can be included for each pixel, as needed or desired. In FIG. 3B, light emitted by pcLEDs of the array 200 is collected directly by projection lens 294 without use of intervening waveguides. This arrangement may particularly be suitable when pcLEDs can be spaced sufficiently close to each other, and may also be used in automobile headlights as well as in camera flash applications or other illumination sources. A miniLED or microLED display application may use similar optical arrangements to those depicted in FIGS. 3A and 3B, for example. Generally, any suitable arrangement of optical elements (primary, secondary, or both) can be used in combination with the pcLEDs described herein, depending on the desired application.

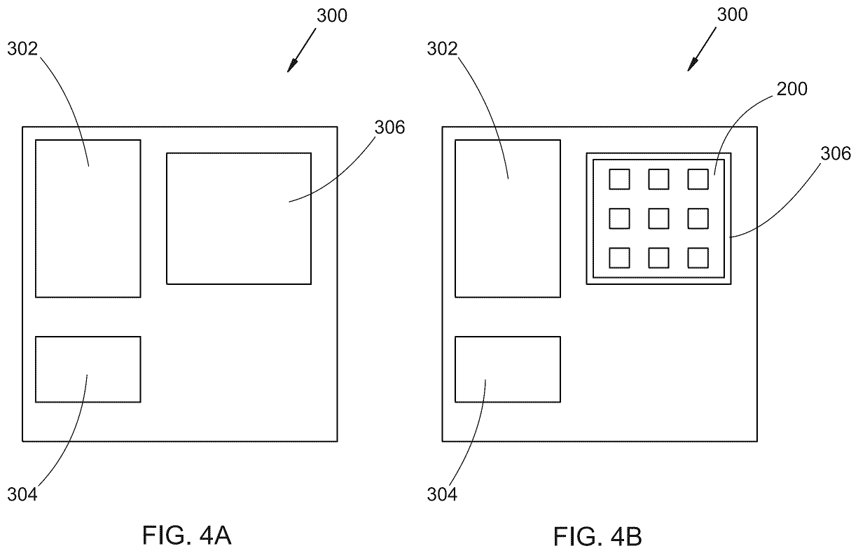

As shown in FIGS. 4A and 4B, a pcLED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, pcLED array 200 may be mounted on a separate board (not shown) from the power and control module and the sensor module.

For purposes of the present disclosure and appended claims, any arrangement of a layer, surface, substrate, diode structure, or other structure “on,” “over,” or “against” another such structure shall encompass arrangements with direct contact between the two structures as well as arrangements including some intervening structure between them. Conversely, any arrangement of a layer, surface, substrate, diode structure, or other structure “directly on,” “directly over,” or “directly against” another such structure shall encompass only arrangements with direct contact between the two structures. For purposes of the present disclosure and appended claims, a layer, structure, or material described as “transparent” and “substantially transparent” shall exhibit, at the wavelength(s) in question, a level of optical transmission that is sufficiently high, or a level of optical loss (due to absorption, scattering, or other loss mechanism) that is sufficiently low, that the light-emitting device can function within operationally acceptable parameters (e.g., output power or luminance, conversion or extraction efficiency, or other figures-of-merit including those described below).

There is a need for luminescent materials (i.e., phosphors) that absorb near-UV or blue light (e.g., light at a first wavelength that is less than 500 nm) and in turn emit red light (e.g., light at a second wavelength that is longer than 600 nm). Such red-emitting luminescent material can be employed for producing red light, e.g., as part of an RGB display, or can be employed for producing white light, e.g., along with light emitted by one or more other phosphors or light at the first wavelength emitted by the semiconductor LED. Several conventional, red-emitting, Eu(II)-doped nitride luminescent materials can be employed, such as CASN (CaAlSiN₃:Eu²⁺) or SCASN ((Sr,Ca)AlSiN₃:Eu²⁺) materials, or BSSNE ((Ba,Sr,Ca)₂Si₅N₈:Eu²⁺) materials.

However, an ongoing need exists for red-emitting luminescent materials with increased luminous efficiency that also provide acceptable color rendition quality or color saturation. Accordingly, examples of inventive nitridophosphate luminescent materials (i.e., phosphors) are disclosed herein that are characterized by more narrow spectral power distributions of the emission bands compared to the conventional red-emitting luminescent materials mentioned above, and that are well suited for e.g. CRI90 white pcLEDs. The example inventive red-emitting luminescent materials disclosed herein can mitigate one issue of conventional red-emitting luminescent materials such as SCASN/CASN-broad emission spectra caused by multisite emission centers—by providing a host lattice with only one site for the emission centers.

An inventive luminescent material comprises a nitridophosphate material having a general formula AE_{y-x}Li_{10-2y}P₄N₁₀:Euₓ, wherein (i) AE includes one or more of Ca, Sr, or Ba, and (ii) y≥x>0. In particular, a red-emitting luminescent material is obtained when y=2 and 0.1>x>0. Other similar materials with, e.g., y=3 or y=4, crystallize in a different structure from that obtained when y=2, and those other materials exhibit emission at shorter wavelengths. In some examples with y=2, the luminescent material exhibits a peak emission wavelength greater than 600 nm; in an example with AE=Ca, y=2, and x=0.01, the luminescent material exhibits a peak emission wavelength at 626 nm. In some examples of the inventive luminescent material, AE includes only Ca. In some other examples, AE includes a majority amount of Ca and lesser amounts of Sr or Ba; inclusion of Sr or Ba shifts the emission to shorter wavelengths. The position of the peak emission can therefore be adjusted by adjusting the ratio of different AE atoms in the inventive luminescent material. Increasing the Eu doping concentration (i.e., increasing x) results in stronger absorption and a shift of the peak emission to longer wavelengths, enabling some degree of tuning the absorptive or emission properties of the inventive luminescent material.

In some examples, the inventive luminescent material can be made by carrying out a solid-state reaction, at an isostatic nitrogen pressure from 50 MPa to 200 MPa and at a temperature from 800° C. to 1000° C., of a mixture of (i) Li₁₀P₄N₁₀, (ii) a halide, hydride, azide, or nitride of AE, and (iii) a halide or oxide of Eu. In one example the reaction proceeds as

$${Li}_{10} {P}_{4} {N}_{10} + ( y - x ) {AE Cl}_{2} + ( x ) {EuCl}_{2} \to {AE}_{y - x} {Li}_{10 \_ 2 y} {P}_{4} {N}_{10} : {Eu}_{x} + ( y + x ) LiCl .$$

The LiCl formed by the solid-state reaction can be removed by washing the luminescent material, e.g., with ethanol.

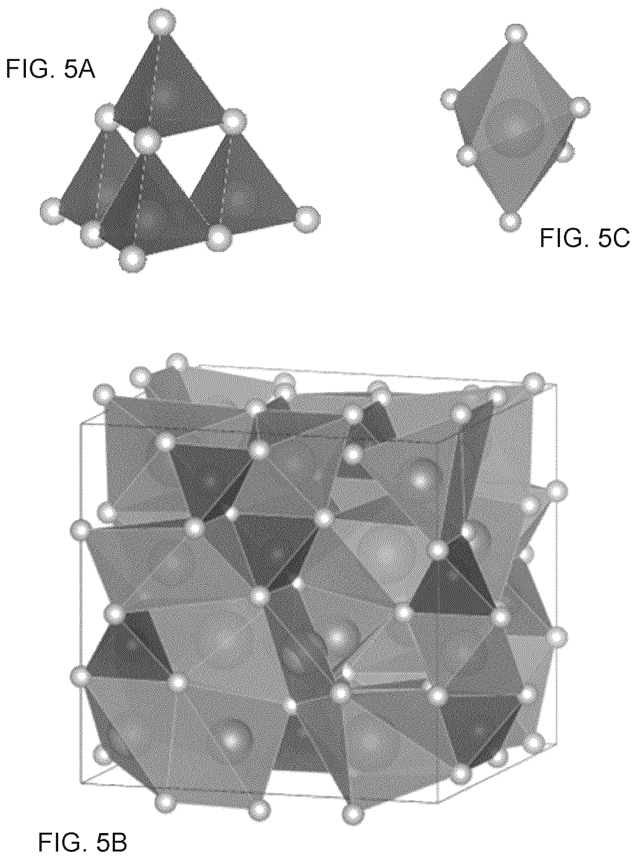

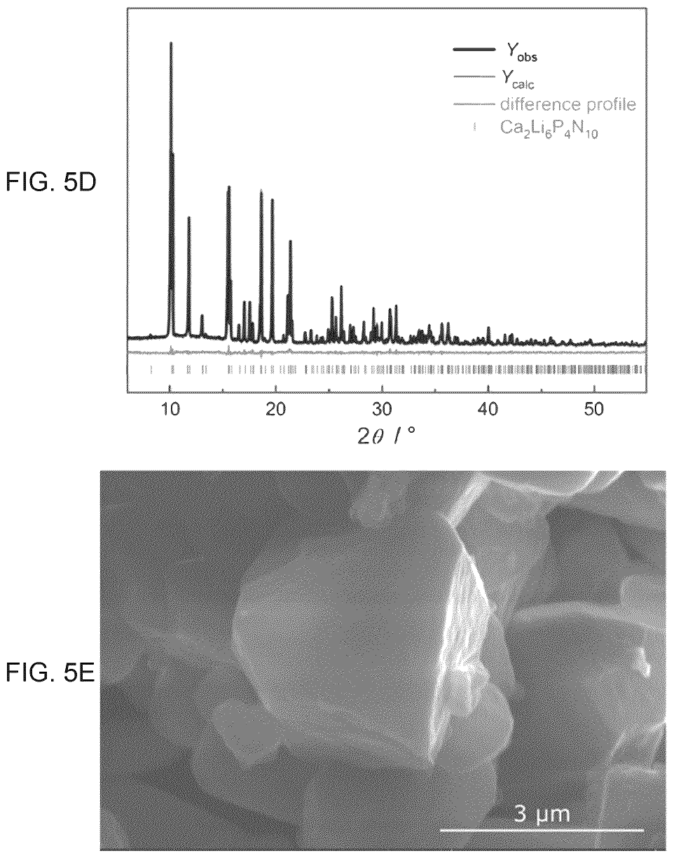

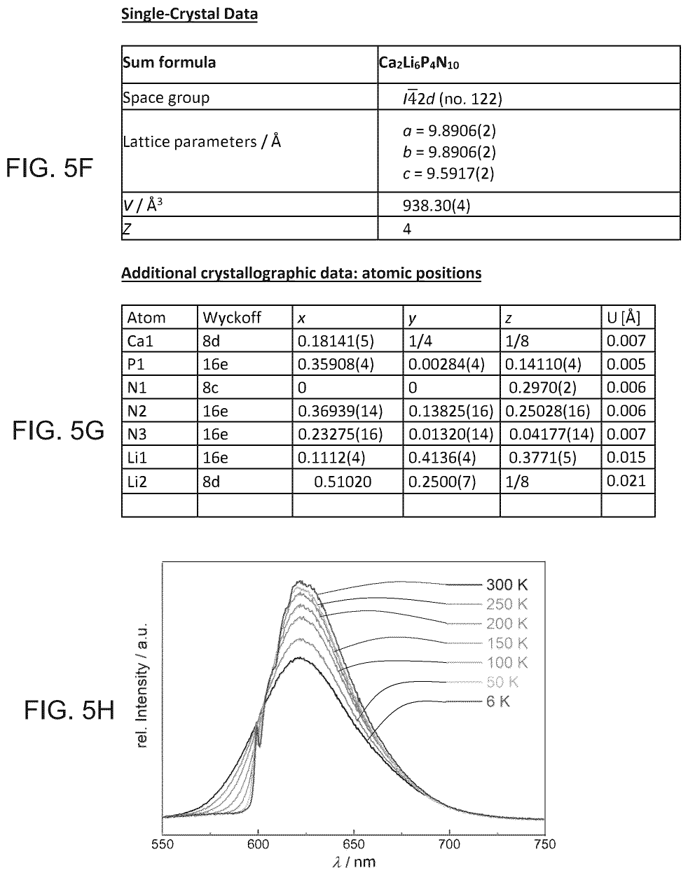

In one particular example, 33.34 g Li₁₀P₄N₁₀, 21.97 g CaCl₂), and 0.45 g EuCl₂ are mixed and fired at 900° C. for 10 hrs under 200 MPa nitrogen pressure in an isostatic pressure furnace. After firing, the raw product can be washed with ethanol to remove LiCl, milled in ethanol with zirconia milling media, and dried. FIG. 5D shows the x-ray powder diffraction pattern of the resulting Ca₂Li₆P₄N₁₀:Eu(1%) phosphor. FIG. 5E shows a scanning electron micrograph of the powder sample.

The [P₄N₁₀]¹⁰⁻ building block (FIG. 5A) of the crystalline structure of the inventive luminescent material suggests the desirability of using Li₁₀P₄N₁₀ as a starting material. In some examples the Li₁₀P₄N₁₀ precursor can be synthesized by solid-state reaction from the binary nitrides Li₃N and P₃N₅ according to the method described in W. Schnick, U. Berger, Angew. Chem. Int. Ed. Engl. 30 (1991) 830-831 (incorporated herein by reference in its entirety). In one particular example, 35.0 g Li₃N is mixed with 65.18 g P₃N₅ (synthesized according to W. Schnick, J. Lücke, F. Krumreich, Chem. Mater. 8 (1996)281-286, which is incorporated herein by reference in its entirety) by planetary ball milling and fired at 800° C. under a nitrogen pressure of 50 MPa.

In some examples, an inventive luminescent compound can be made by a solid-state reaction, at an isostatic nitrogen pressure from 50 MPa to 200 MPa and at a temperature from 800° C. to 1000° C., of a mixture of (i) AE₂PN₃:Eu, (ii) LiPN₂, and (iii) Li₃N. In some examples an inventive luminescent material can be made according to (Ca,Sr)₂PN₃:Eu+5 LiPN₂+(⅓)Li₃N→(Ca,Sr)₂Li₆P⁴N₁₀:Eu. Lithium nitride melts at around 814° C.; in some examples the lithium nitride can serve as a flux. In some examples a small excess of lithium nitride enhance phase formation and can be used to control the grain size of the phosphor powder that is produced by the reaction.

In some other examples other starting materials can be employed for phosphor synthesis. For example, hydrides, azides, or nitrides can be used as AE sources, such as AE(N₃)₂, AEH₂, AE₂N, or AE³N₂. These precursors can be combined with Li₃N or LiN₃ as Li sources and P (red) or P₃N₅ as P sources. For Eu doping, compounds such as Eu chloride, fluoride, or oxide can be employed. Alternatively, in some examples alkaline earth or lithium phosphides such as AE₃P₂, AEP₃, AE₂P₂, AE₅P₈, LiP, or Li₃P can be employed as precursors for the synthesis of the inventive nitridophosphate luminescent material. In some examples Ca₃P₂ can be formed by carbothermal reduction (Ca₃(PO₄)₂+8C→Ca₃P₂+8 CO). In some examples, more complex precursor materials can be employed for the synthesis of an inventive luminescent material. In some examples ternary nitridophosphates such as LiPN₂, Li₁₂P₃N₉, Li₇PN₄, Li₆P₃N₇, Li₅P₂N₅, or Ca₂PN₃ can be employed.

AE₂₋ₓLi₆P₄N₁₀:Euₓ (AE=Ca, Sr, Ba) crystallizes in the tetragonal space group 142d (Nr. 122). For AE=Ca lattice parameters are a=b=9.891 Å and c=9.592 Å. The tables shown in FIGS. 5F and 5G include data from the crystal structure analysis, derived from the X-ray diffraction pattern shown in FIG. 5D. The [P₄N₁₀]¹⁰⁻ building block of the crystalline structure of the inventive luminescent materials is illustrated schematically in FIG. 5A; FIG. 5B illustrates schematically a unit cell of the crystal structure, which includes 4 formula units. The AE atoms that are partially substituted by Eu atoms (the largest balls in FIG. 5B) are located on one lattice site that is coordinated by 6 N atoms forming a distorted octahedron, illustrated schematically in FIG. 5C. The single lattice site for the Eu dopant leads to a clearly resolved zero phonon emission line under blue light excitation and low phosphor temperatures (FIG. 5H).

In some examples a phosphor particle coating can be applied to the raw phosphor particles, so as to enhance the long-term reliability of the phosphor powder. In some examples such a coating can be formed, e.g., by an atomic layer deposition (ALD) process or by a sol-gel coating process. Examples are disclosed in, e.g., US Pat. Pub. No. 2021/0403805, which is incorporated by reference in its entirety.

An inventive wavelength-converting structure comprises a nitridophosphate material having a general formula AE_{y-x}Li_{10-2y}P₄N₁₀:Euₓ, wherein (i) AE includes one or more of Ca, Sr, or Ba, and (ii) y≥x>0, including any of the examples shown or described herein. A method for making such an inventive wavelength-converting structure comprises binding together particles of inventive luminescent material in a polymer (e.g., silicone) or ceramic binder material. As noted above, in some examples, before binding together the particles of the inventive luminescent material, a particle coating can be formed on the particles of the luminescent material. In some examples, before binding, particles of one or more additional luminescent materials can be mixed with particles of the inventive luminescent material. The mixture of luminescent material particles can then be bound using a polymer or ceramic binder material.

An inventive light-emitting device can comprise a Ill-nitride light-emitting diode (LED 102) and an inventive wavelength-converting structure 106 that includes an inventive luminescent material, including any of those shown or described herein. The LED 102 (e.g., a Ill-nitride LED) can be arranged so as to emit light at a first wavelength (e.g., shorter than 500 nm) that is at least partly absorbed by the inventive luminescent material. The luminescent material absorbs at least some of the light at the first wavelength and in turn emits light at a second, longer wavelength (e.g., longer than 600 nm). The light-emitting device can be operated by supplying electrical current to the semiconductor LED 102 so that (i) the semiconductor LED 102 emits the light at the first wavelength, and (ii) absorption of at least a portion of the light at the first wavelength by the luminescent material of the wavelength-converting structure 106 results in emission of the light at the second wavelength. The output light of the light-emitting device 100 includes the light at the second wavelength. In some examples, the light at the first wavelength can be absent from or only negligibly present in the output light of the light-emitting device 100; in such examples, the output light might be red, so that the light-emitting device can serve as, e.g., a red pixel in an RGB display. In some other examples, a portion of the light at the first wavelength can be included in the output light of the light-emitting device; in such examples the output light can be, e.g., white light resulting from a mixture of the light at the first and second wavelengths. In some of those examples, the wavelength-converting structure 106 can include one or more additional luminescent materials that emit light at one or more additional wavelength that are longer than the first wavelength.

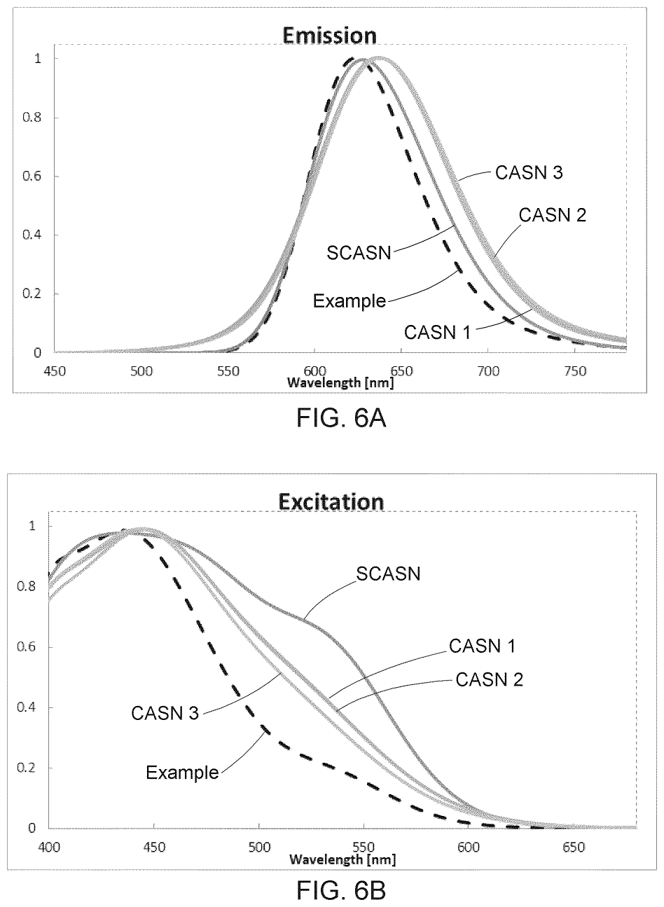

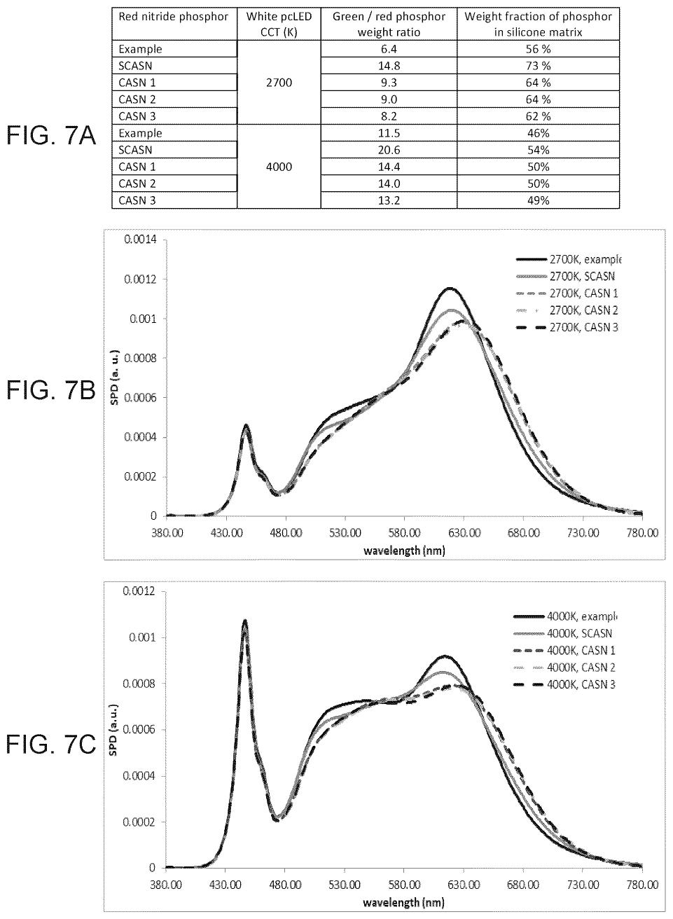

A comparison of an example of an inventive luminescent material (Ca₂Li₆P₄N₁₀:Eu(1%); designated as Example in FIGS. 6A, 6B, and 7A-7C) was compared to several conventional red-emitting luminescent materials (designated SCASN, CASN1, CASN2, and CASN3, e.g., sourced from Mitsubishi Chemical Corporation and labeled as BR3/639A, BR101/N, BR101/J, and BR101/D, respectively). FIG. 6A shows a comparison of normalized emission spectra obtained with excitation at 440 nm. FIG. 6B shows a comparison of normalized excitation spectra. The example inventive luminescent material and the conventional luminescent materials were each mixed in a two-component silicone resin with a green-emitting Ce(III)-doped yttrium aluminum gallium garnet phosphor with a unit cell constant a=12.09 Å and a Ga/Al ratio of ½ showing an emission luminous efficiency of radiation (LER) of 465 lm/W. For each red-emitting phosphor (inventive and conventional) two samples were made: one exhibiting a correlated color temperature (CCT) of 2700 K and another exhibiting a CCT of 4000 K; parameters of the samples are shown in the table of FIG. 7A. The phosphor in silicone suspensions were then dispensed into 2.8×3.5 mm² lead frame LED packages equipped with blue InGaN die (440 nm centroid wavelength). After curing the silicone the resulting pcLEDs were characterized at 25° C. and 120 mA of LED current.

FIGS. 7B and 7C show the spectral power distributions of the white pcLEDs for correlated color temperatures of 2700 and 4000K, respectively. The samples with a correlated color temperature of 2700 K exhibited CIE x,y color coordinates of x=0.485, y=0.410; the samples with a color temperature of 4000 K exhibited Commission Internationale de L'éclairage (CIE) x,y color coordinates of x=0.382, y=0.380, A reduction of the spectral power in the deep red (>650 nm) range for white pcLEDs that include the inventive nitridophosphate phosphor can be observed. This reduced deep-red-light content not only leads to an increase of the luminous efficacy of radiation but also to an increase in light quality, measured by the average color rendering index Ra8.

In addition to the preceding, the following example embodiments fall within the scope of the present disclosure or appended claims:

Example 1. A luminescent material comprising a nitridophosphate material having a general formula AE_{y-x}Li_{10-2y}P₄N₁₀:Euₓ, wherein (i) AE includes one or more of Ca, Sr, or Ba, and (ii) y≥x>0.

Example 2. The luminescent material of Example 1 wherein y=2 and 0.1>x>0.

Example 3. The luminescent material of any one of Examples 1 or 2 wherein AE includes only Ca.

Example 4. The luminescent material of any one of Examples 1 or 2 wherein AE includes a majority amount of Ca and lesser amounts of Sr or Ba.

Example 5. The luminescent material of any one of Examples 1 through 4, the luminescent material exhibiting a peak emission wavelength greater than 600 nm.

Example 6. A method for making the luminescent material of any one of Examples 1 through 5, the method comprising carrying out a solid-state reaction, at an isostatic nitrogen pressure from 50 MPa to 200 MPa and at a temperature from 800° C. to 1000° C., of a mixture of (i) Li₁₀P₄N₁₀, (ii) a halide, hydride, azide, or nitride of AE, and (iii) a halide or oxide of Eu.

Example 7. The method of Example 6 further comprising washing the luminescent material to remove LiCl formed by the solid-state reaction.

Example 8. A method for making the luminescent material of any one of Examples 1 through 5, the method comprising carrying out a solid-state reaction, at an isostatic nitrogen pressure from 50 MPa to 200 MPa and at a temperature from 800° C. to 1000° C., of a mixture of (i) AE₂PN₃:Eu, (ii) LiPN₂, and (iii) Li₃N.

Example 9. A wavelength-converting structure comprising the luminescent material of any one of Examples 1 through 5.

Example 10. A method for making the wavelength-converting structure of Example 9, the method comprising binding together particles of the luminescent material in a polymer or ceramic binder material.

Example 11. A method for making the wavelength-converting structure of Example 9, the method comprising (i) mixing particles of the luminescent material with particles of one or more additional luminescent materials, and (ii) binding together the particles of the luminescent material and the particles of the one or more additional luminescent materials in a polymer or ceramic binder.

Example 12. The method of any one of Examples 10 or 11 further comprising, before binding together the particles of the luminescent material(s), forming a particle coating on the particles of the luminescent material(s).

Example 13. A light-emitting device comprising a Ill-nitride light-emitting diode (LED) and the wavelength-converting structure of Example 9, the LED being arranged so as to emit light at a first wavelength that is at least partly absorbed by the luminescent material, the luminescent material exhibiting emission of light at a second wavelength, the emission resulting from absorption of the light at the first wavelength, the second wavelength being longer than the first wavelength.

Example 14. A light-emitting device comprising a Ill-nitride light-emitting diode (LED) and the wavelength-converting structure of Example 9, the LED being arranged so as to emit light, at a first wavelength that is less than 500 nm, that is at least partly absorbed by the luminescent material of the wavelength-converting structure, the luminescent material exhibiting emission of light at a second wavelength that is greater than 600 nm, the emission resulting from absorption of the light at the first wavelength.

Example 15. A method for operating the light-emitting device of any one of Examples 13 or 14, the method comprising supplying electrical current to the LED so that (i) the LED emits the light at the first wavelength, and (ii) absorption of at least a portion of the light at the first wavelength by the luminescent material of the wavelength-converting structure results in emission of the light at the second wavelength, the light at the second wavelength being included in output light of the light-emitting device.

Example 16. The method of Example 15, the light at the first wavelength being absent from or only negligibly present in the output light of the light-emitting device.

Example 17. The method of Example 15, a portion of the light at the first wavelength being included in the output light of the light-emitting device.

Example 18. The method of any one of Examples 15 through 17, the wavelength-converting structure including one or more additional luminescent materials, absorption of at least a portion of the light at the first wavelength by each of the one or more additional luminescent materials of the wavelength-converting structure resulting in emission of the light at a corresponding additional wavelength that is longer than the first wavelength, the output light of the light-emitting device including the light emitted by the one or more additional luminescent materials of the wavelength-converting structure.

This disclosure is illustrative and not limiting. Further modifications will be apparent to one skilled in the art in light of this disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of any single disclosed example embodiment. Therefore, the present disclosure shall be construed as implicitly disclosing any embodiment having any suitable subset of one or more features-which features are shown, described, or claimed in the present application-including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either . . . or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each.

For purposes of the present disclosure or appended claims, when a numerical quantity is recited (with or without terms such as “about,” “about equal to,” “substantially equal to,” “greater than about,” “less than about,” and so forth), standard conventions pertaining to measurement precision, rounding error, and significant digits shall apply, unless a differing interpretation is explicitly set forth. For null quantities described by phrases such as “prevented,” “absent,” “eliminated,” “equal to zero,” “negligible,” and so forth (with or without terms such as “substantially” or “about”), each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled.

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim. In the appended claims, if the provisions of 35 USC § 112 (f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC § 112 (f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A luminescent material comprising a nitridophosphate material having a general formula AE_{y-x}Li_{10-2y}P₄N₁₀:Euₓ, wherein (i) AE includes one or more of Ca, Sr, or Ba, and (ii) y≥x>0.

2. The luminescent material of claim 1 wherein y=2 and 0.1>x>0.

3. The luminescent material of claim 2 wherein AE includes only Ca.

4. The luminescent material of claim 2 wherein AE includes a majority amount of Ca and lesser amounts of Sr or Ba.

5. The luminescent material of claim 2, the luminescent material exhibiting a peak emission wavelength greater than 600 nm.

6. A method for making the luminescent material of claim 1, the method comprising carrying out a solid-state reaction, at an isostatic nitrogen pressure from 50 MPa to 200 MPa and at a temperature from 800° C. to 1000° C., of a mixture of (i) Li₁₀P₄N₁₀, (ii) a halide, hydride, azide, or nitride of AE, and (iii) a halide or oxide of Eu.

7. The method of claim 6 further comprising washing the luminescent material to remove LiCl formed by the solid-state reaction.

8. A method for making the luminescent material of claim 1, the method comprising carrying out a solid-state reaction, at an isostatic nitrogen pressure from 50 MPa to 200 MPa and at a temperature from 800° C. to 1000° C., of a mixture of (i) AE₂PN₃:Eu, (ii) LiPN₂, and (iii) Li₃N.

9. A wavelength-converting structure comprising a nitridophosphate luminescent material having a general formula AE_{y-x}Li_{10-2y}P₄N₁₀:Euₓ, wherein (i) AE includes one or more of Ca, Sr, or Ba, and (ii) y≥x>0.

10. A method for making the wavelength-converting structure of claim 9, the method comprising binding together particles of the nitridophosphate luminescent material in a polymer or ceramic binder material.

11. The method of claim 10 further comprising, before binding together the particles of the nitridophosphate luminescent material, forming a particle coating on the particles of the nitridophosphate luminescent material.

12. A method for making the wavelength-converting structure of claim 9, the method comprising (i) mixing particles of the nitridophosphate luminescent material with particles of one or more additional luminescent materials, and (ii) binding together the particles of the nitridophosphate luminescent material and the particles of the one or more additional luminescent materials in a polymer or ceramic binder.

13. A light-emitting device comprising a Ill-nitride light-emitting diode (LED) and the wavelength-converting structure of claim 9, the LED being arranged so as to emit light at a first wavelength that is at least partly absorbed by the luminescent material, the nitridophosphate luminescent material exhibiting emission of light at a second wavelength, the emission resulting from absorption of the light at the first wavelength, the second wavelength being longer than the first wavelength.

14. The wavelength-converting structure of claim 9 wherein y=2 and 0.1>x>0.

15. The wavelength-converting structure of claim 14 wherein AE includes only Ca.

16. The wavelength-converting structure of claim 14 wherein AE includes a majority amount of Ca and lesser amounts of Sr or Ba.

17. The wavelength-converting structure of claim 14, the nitridophosphate luminescent material exhibiting a peak emission wavelength greater than 600 nm.

18. A light-emitting device comprising a Ill-nitride light-emitting diode (LED) and the wavelength-converting structure of claim 17, the LED being arranged so as to emit light, at a first wavelength that is less than 500 nm, that is at least partly absorbed by the nitridophosphate luminescent material of the wavelength-converting structure, the nitridophosphate luminescent material exhibiting emission of light at a second wavelength that is greater than 600 nm, the emission resulting from absorption of the light at the first wavelength.

19. A method for operating the light-emitting device of claim 18, the method comprising supplying electrical current to the LED so that (i) the LED emits the light at the first wavelength, and (ii) absorption of at least a portion of the light at the first wavelength by the nitridophosphate luminescent material of the wavelength-converting structure results in emission of the light at the second wavelength, the light at the second wavelength being included in output light of the light-emitting device.

20. The method of claim 19, the light at the first wavelength being absent from or only negligibly present in the output light of the light-emitting device.

21. The method of claim 19, a portion of the light at the first wavelength being included in the output light of the light-emitting device.

22. The method of claim 19, the wavelength-converting structure including one or more additional luminescent materials, absorption of at least a portion of the light at the first wavelength by each of the one or more additional luminescent materials of the wavelength-converting structure resulting in emission of the light at a corresponding additional wavelength that is longer than the first wavelength, the output light of the light-emitting device including the light emitted by the one or more additional luminescent materials of the wavelength-converting structure.
